(19) United States
(12) Patent Application Publication
(10) Pub. No.: US 2025/0359385 A1
(43) Pub. Date: Nov. 20, 2025

(54) CHIP PACKAGE AND METHOD FOR FORMING THE SAME

(71) Applicant: Xintec Inc., Taoyuan City (TW)

(72) Inventors: Kuei-Wei CHEN, Taoyuan City (TW); Yueh Hsien LI, Hsinchu City (TW); Yi-Xuan HUANG, Taoyuan City (TW)

(21) Appl. No.: 19/060,488

(22) Filed: Feb. 21, 2025

Related U.S. Application Data
(60) Provisional application No. 63/648,056, filed on May 15, 2024.

(51) Int. Cl. H10F 39/00

(52) U.S. Cl. CPC H10F 39/811; H10F 39/026; H10F 39/804

(57) ABSTRACT

A chip package is provided. The chip package includes a device substrate, a metallization layer, a first redistribution layer (RDL), a passivation layer structure, and an etch stop layer. The metallization layer and the first redistribution layer are respectively disposed on the front-side surface and the backside surface of the device substrate. The passivation layer structure covers the edge surface surrounding the device substrate. The passivation layer structure extends onto the backside surface and covers the first RDL. The etch stop layer is disposed in the metallization layer. The etch stop layer is aligned with the passivation layer structure covering the edge surface, so as to surround the device substrate.

### CROSS REFERENCE TO RELATED APPLICATIONS

This application claims the benefit of U.S. Provisional Application No. 63/648,056, filed May 15, 2024, the entirety of which is incorporated by reference herein.

### BACKGROUND OF THE INVENTION

### Field of the Invention

The invention relates in general to a packaging technology, and in particular it relates to a chip package with improved chip structure strength and a method for forming the same.

### Description of the Related Art

Optoelectronic devices are widely used in electronic products such as desktops, tablets, digital cameras, mobile phones, digital video recorders and the like. The chip package process is an important step in the fabrication of electronic products. Chip packages not only protect optoelectronic components from outside environmental contaminants, but they also provide electrical connection paths between the optoelectronic components and exterior circuits.

With the development of semiconductor technology and chip packaging technology, the size of the chip may also change, causing the chip packaging technology to face many challenges. For example, when a thin chip is mounted into a package, such a chip may warp or deform due to insufficient rigidity of the chip itself, and hence chip packaging becomes more difficult.

Therefore, it is necessary to seek a chip package and a method for forming the same that are capable of addressing or mitigating the problems described above.

### BRIEF SUMMARY OF THE INVENTION

In some embodiments, a chip package is provided. The chip package includes a device substrate has an edge surface surrounding the device substrate. The chip package also includes a metallization layer and a first redistribution layer respectively disposed on a front side surface and a backside surface of the device substrate, and the first redistribution layer also extends into the device substrate. The chip package further includes a passivation layer structure and a stop layer. The passivation layer structure surrounds and covers the edge surface of the device substrate, and extends to the backside surface and covers the first redistribution layer. The stop layer is disposed within the metallization layer and is aligned with the passivation layer structure covering the edge surface to surround the device substrate.

In some embodiments, a method for forming a chip package is provided. The method includes providing a substrate. The substrate has a chip region and a scribe line region surrounding the chip region C. The above method also includes forming a metallization layer on the front side surface of the substrate, and the metallization layer has a first opening aligned with the scribe line region and surrounding the chip region C. The method further includes forming a stop layer in the first opening, and forming a first redistribution layer on the backside surface of the substrate and extending into the substrate. In addition, the above method includes forming a second opening in the substrate and aligned with the scribe line region to surround the chip region and expose the stop layer. The above method also includes forming a passivation layer structure on the backside surface. The passivation layer structure fills the second opening and covers the first redistribution layer.

### BRIEF DESCRIPTION OF THE DRAWINGS

The present disclosure can be more fully understood by reading the subsequent detailed description and examples with references made to the accompanying drawings, wherein:

FIGS. 1A to 1J are cross-sectional views of a method for forming a chip package according to some embodiments.

FIG. 2 is a cross-sectional view of a chip package according to some embodiments.

FIGS. 3A to 3E are cross-sectional views of a method for forming a chip package according to some embodiments.

FIG. 4 is a cross-sectional view of a chip package according to some embodiments.

FIGS. 5A to 5H are cross-sectional views of a method for forming a chip package according to some embodiments.

FIG. 6 is a cross-sectional view of a chip package according to some embodiments.

FIG. 7 is a cross-sectional view of a chip package according to some embodiments.

FIG. 8 is a cross-sectional view of a chip package according to some embodiments.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed. Moreover, when a first material layer is referred to as being on or overlying a second material layer, the first material layer may be in direct contact with the second material layer, or separated from the second material layer by one or more material layers.

A chip package according to some embodiments of the present disclosure may be used to package micro-electro-mechanical system chips. However, embodiments of the invention are not limited thereto. For example, the chip package of the embodiments of the invention may be implemented to package active or passive devices or electronic components of integrated circuits, such as digital or analog circuits. For example, the chip package is related to optoelectronic devices, micro-electro-mechanical systems (MEMS), biometric devices, micro fluidic systems, and physical sensors measuring changes to physical quantities such as heat, light, capacitance, pressure, and so on. In particular, a wafer-level package (WSP) process may optionally be used to package semiconductor chips, such as image-sensor elements, light-emitting diodes (LEDs), solar cells, RF circuits, accelerators, gyroscopes, fingerprint recognition devices, micro actuators, surface acoustic wave devices, pressure sensors, ink printer heads, and so on.

The above-mentioned wafer-level package process mainly means that after the packaging step is accomplished during the wafer stage, the wafer with chips is cut to obtain individual packages. However, in a specific embodiment, separated semiconductor chips may be redistributed on a carrier wafer and then packaged, which may also be referred to as a wafer-level package process. In addition, the above-mentioned wafer-level package process may also be adapted to form a chip package having multi-layer integrated circuit devices by a stack of a plurality of wafers having integrated circuits.

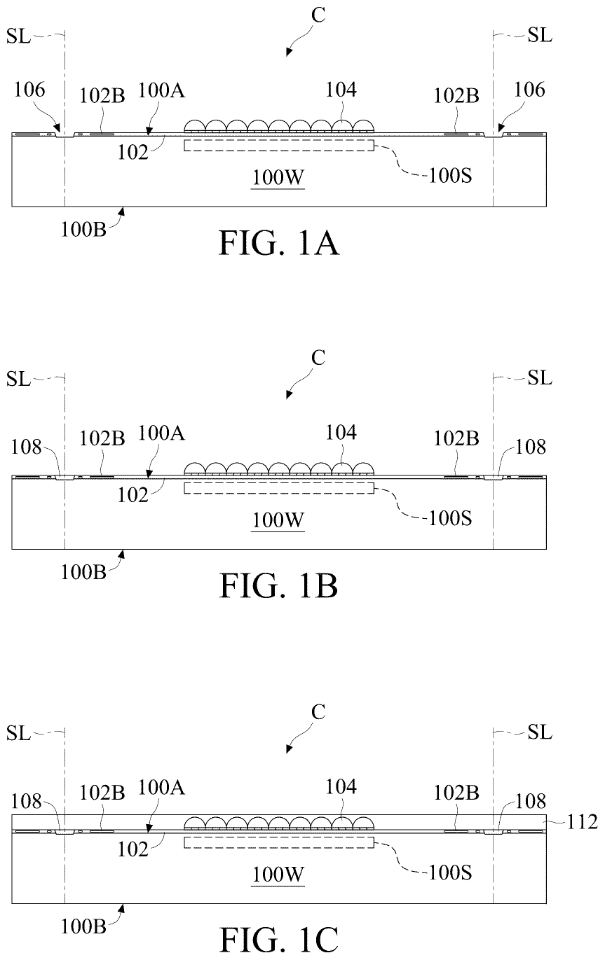

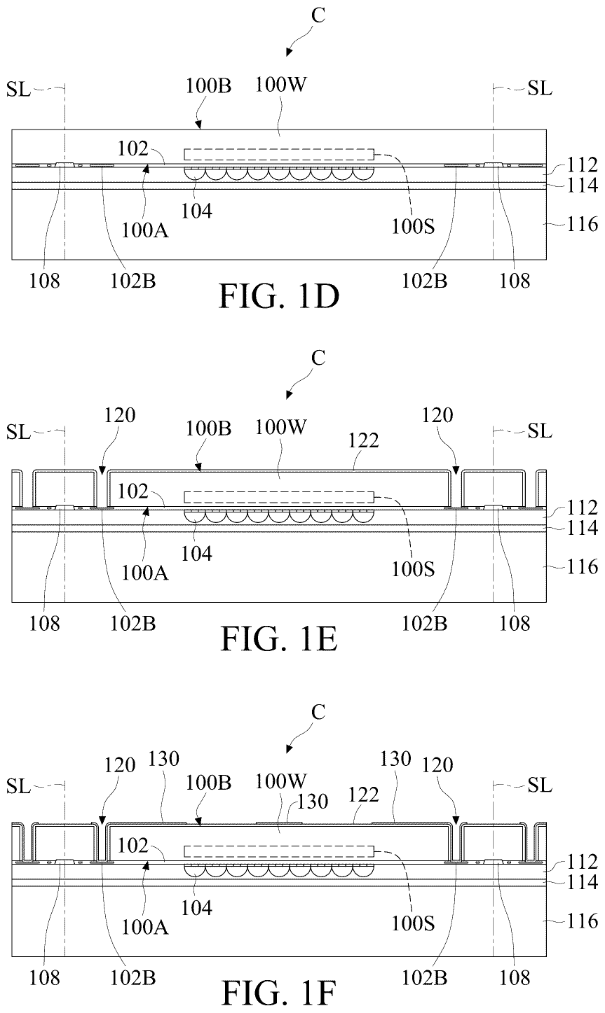

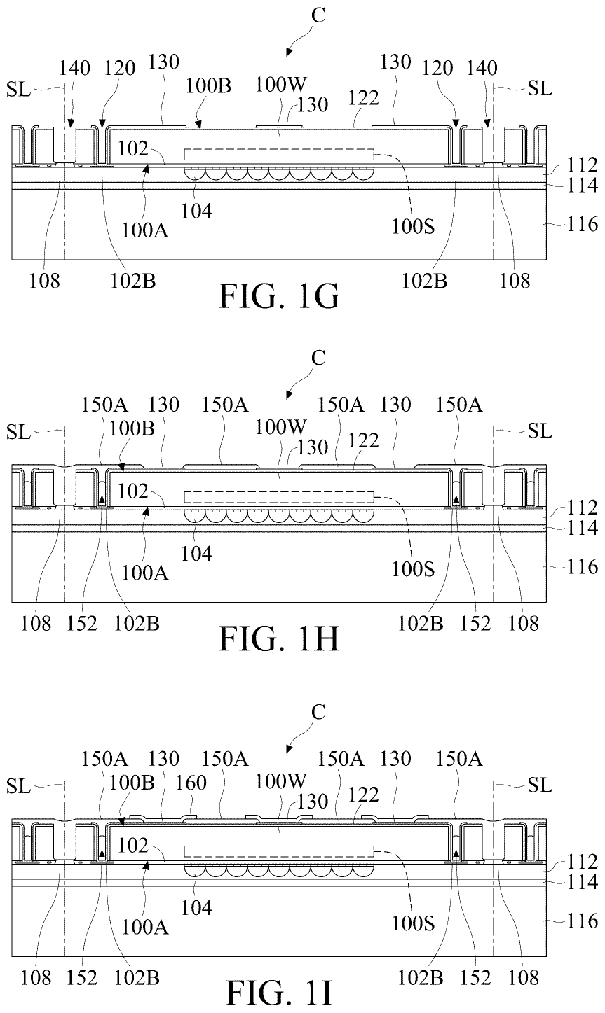

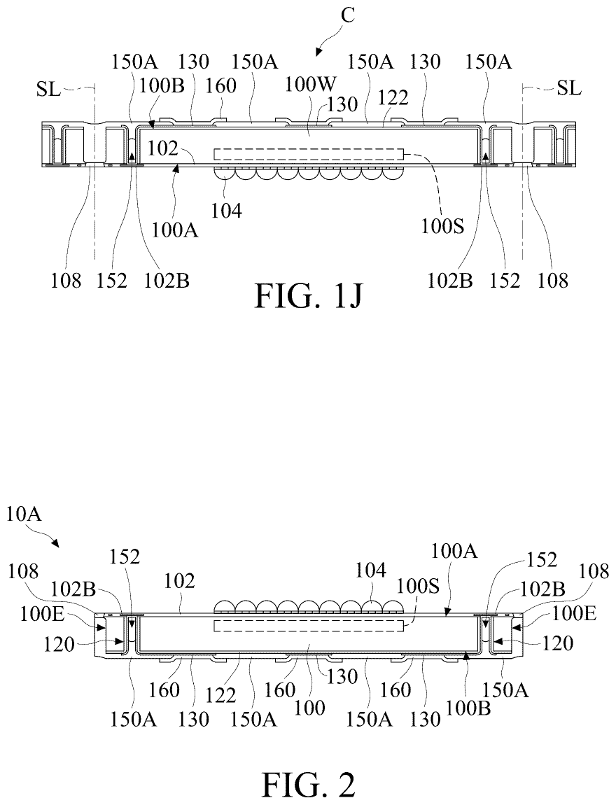

FIGS. 1A to 1J are cross-sectional views of a method for forming a chip package according to some embodiment. In some embodiments, the chip package is implemented with a front side illumination (FSI) sensing device. Refer to FIG. 1A, in which a substrate 100W is provided. The substrate 100W has a front side surface 100A (e.g., active surface) and a backside surface 100B (e.g., non-active surface) opposite the front side surface 100A. The substrate 100W has chip regions (not shown) and a scribe line region surrounding the chip regions and separating adjacent chip regions C. To simplify the diagram, only a complete chip region C and a scribe line region SL (indicated by a dotted line) that separates the chip region C is depicted. In some embodiments, the substrate 100W is a silicon wafer or other suitable semiconductor wafer to facilitate the wafer level packaging process. In some other embodiments, the substrate 100W is a silicon substrate or other semiconductor substrate. In some embodiments, the substrate 100W in the chip region C includes a circuit (not shown), and signals are input and output via the subsequently formed pads.

Moreover, a metallization layer 102 and one or more conductive pad 102B are disposed on the front side surface 100A of the substrate 100W. In some embodiments, the metallization layer 102 formed on the front side surface 100A includes an interlayer dielectric (ILD) layer, an inter-metal dielectric (IMD) layer, and a passivation layer, or a combination thereof. To simplify the diagram, only a flat layer is depicted herein. In some embodiments, the metallization layer 102 has an opening 106 aligned with the scribe line region SL to surround the chip region C. The opening 106 may penetrate the metallization layer 102 and partially extend into the substrate 100W from the front side surface 100A. The opening 106 may be formed via a laser grooving process. The opening 106 corresponding to the scribe line region SL and formed by laser grooving can mitigate the reduction of reliability due to cracking of the metallization layer 102 that is formed of a low dielectric material.

In some embodiments, before forming the opening 106, the conductive pads 102B are formed in the metallization layer 102, and the optical components 104 are correspondingly formed on the metallization layer 102 of each chip region C. In some embodiments, the conductive pad 102B serves as an input/output (I/O) pad and is be a single-layer structure or a multi-layer structure. In order to simplify the diagram, only the conductive pad 102B with a single-layer structure is depicted as an example. The conductive pad 102B may include metallic materials, such as copper, aluminum, a combination thereof, or another suitable pad material. It can be understood that the number of conductive pads 102B depends on design demands and is not limited to the embodiment shown in FIG. 1A.

In some embodiments, the optical component 104 is correspondingly formed on the metallization layer 102 of each chip region C, and corresponds to a sensing region of the substrate 100W of each chip region C. The optical component 104 may include a microlens array, a filter layer, a combination thereof, or another suitable optical component. The sensing region includes a sensing device 100S adjacent to the front side surface 100A of the substrate 100W. For example, the sensing device may be an image sensing device or another suitable sensing device. In some other embodiments, the sensing device includes a device for sensing biometric identification (e.g., a fingerprint recognition device), a device for sensing environmental characteristics (e.g., a temperature sensing device, a humidity sensing device, a pressure sensing device, capacitive sensing device) or another suitable sensing device.

Referring to FIG. 1B, after forming the opening 106, a stop layer 108 is formed in the opening 106. The stop layer 108 may serve as a stop layer for subsequent pre-sawing processes (e.g., dicing saw processes). In addition, the stop layer 108 can also serve as a stress buffer layer to protect the adjacent metallization layer 102 during the dicing saw process. In some embodiments, the stop layer 108 includes epoxy resin, organic polymer materials (e.g., polyimide, butylcyclobutene (BCB), parylene, polynaphthalene, fluorocarbons, acrylates), photoresist materials or other suitable insulating materials.

Referring to FIG. 1C, in some embodiments, after forming the stop layer 108, an adhesive layer 112 is formed on the metallization layer 102 and covers the optical component 104. The adhesive layer 112 serves as a temporary bonding layer, so as to provide a flat surface for the structure shown in FIG. 1B, thereby facilitating attaching the front side surface 100A of the substrate 100W to a carrier substrate.

Referring to FIG. 1D, in some embodiments, after forming the adhesive layer 112, the carrier substrate 116 is attached to the adhesive layer 112 via a tape layer 114 to temporarily attach the substrate 100W onto the carrier substrate 116. For example, the adhesive layer 112 and the tape layer 114 may include temporary bonding materials such as a light-to-heat conversion (LTHC), ultraviolet curing or thermal curing material. In addition, the carrier substrate 116 may be made of silicon, glass, ceramic or a suitable material, and may have a wafer shape to facilitate the wafer level packaging process. For example, the carrier substrate 116 is a glass wafer and serves as a temporary support structure during the manufacturing of the substrate 100W. In some embodiments, the adhesive layer 112 can be used as a bonding layer between the carrier substrate 116 and other structures, so as to temporarily bond the carrier substrate 116 and other structures together.

Afterwards, a thinning process (e.g., etching process, milling process, grinding process or polishing process) is performed on the backside surface 100B of the substrate 100W to reduce the thickness of the substrate 100W.

Referring to FIG. 1E, in some embodiments, after the thinning process, one or more openings 120 are formed in the substrate 100W. The openings 120 extend from the backside surface 100B to the front side surface 100A of the substrate. For example, the one or more openings 120 can be formed in the substrate 100W of each chip region C via a photolithography process and an etching process (e.g., a dry etching process, a wet etching process, a plasma etching process, a reactive ion etching process, or another suitable process). The opening 120 penetrates the substrate 100W and extends into the metallization layer 102 to expose the conductive pad 102B.

Next, an insulating liner 122 (which may be referred to as an electrical isolation layer) is conformally formed on the backside surface 100B of the substrate 100W. The insulating liner 122 is also conformally deposited on the sidewall surface of the opening 120. In some embodiments, the insulating liner 122 may be silicon oxide or another suitable insulating material. For example, the insulating liner 122 made of silicon oxide may be formed via a deposition process (e.g., a thermal oxidation process, a spin on process, a physical vapor deposition process, a chemical vapor deposition process, or another suitable processes).

Referring to FIG. 1F, in some embodiments, patterned redistribution layers (RDLs) 130 is formed on the insulating liner 122 above the backside surface 100B of the substrate 100W. In some embodiments, the patterned RDL 130 can be formed successively through a deposition process (for example, a spin coating process, a physical vapor deposition process, a chemical vapor deposition process, an electroplating process, an electroless plating process, or other suitable processes), a lithography process, and an etching process. For example, a conductive layer (not shown) can be conformally formed on the insulating liner 122 using an electroplating process. The conductive layer is also conformally formed on the insulating liner 122 located on the sidewall surface of the opening 120, and directly electrically contacts or indirectly electrically connects the exposed conductive pad 102B through the opening 120. Afterwards, the conductive layer is patterned successively through a photolithography process and an etching process to form the RDLs 130. The conductive layer may include aluminum, titanium, tungsten, copper or combinations thereof or other suitable conductive materials.

In some embodiments, the RDLs 130 are formed on the backside surface 100B of the substrate 100W, and conformally extend to the sidewall surface and the bottom surface of the opening 120. The RDL 130 is electrically isolated from the substrate 100W via the insulating liner 122, and is directly or indirectly electrically connected to the exposed conductive pad 102B through the opening 120. As a result, the RDL 130 in the opening 120 forms a through-substrate via (TSV).

Referring to FIG. 1G, in some embodiments, an opening 140 is formed in the substrate 100W and aligned with the scribe line region SL to surround the chip region C and expose the stop layer 108 in the metallization layer 102. In some embodiments, a dicing saw process may be performed along the scribe line region SL to form an opening 140. In some embodiments, the opening 140 extends through the substrate 100W and partially extends into the stop layer 108. For example, the opening 140 extends half the thickness of the stop layer 108. In some other embodiments, the opening 140 extends through the substrate 100W but does not extend into the stop layer 108.

Referring to FIG. 1H, in some embodiments, a passivation layer structure is formed on the backside surface 100B of the substrate 100W. The passivation layer structure covers the RDLs 130 and extends into the openings 120 and 140. In some embodiments, the passivation layer structure has a single-layer structure. For example, the passivation layer structure is composed of a single-layer passivation layer 150A. Afterwards, the single-layer passivation layer 150A is patterned, so that openings are formed in the patterned single-layer passivation layer 150A to expose the underlying RDLs 130. The portions of the RDLs 130 exposed through the openings serve as pad regions for electrically connecting to external circuits (not shown). The single-layer passivation layer 150A may be made of a single layer of organic polymer material (for example, examples of organic polymer materials include polyimide resin, benzene cyclobutene (BCB), parylene, naphthalene polymer, fluorocarbon and acrylic) layers.

As shown in FIG. 1H, a single-layer passivation layer 150A blocks the openings 120 and 140. In some embodiments, the single-layer passivation layer 150A completely fills the opening 140 but does not completely fill the opening 120. For example, a hole 152 is formed between the single-layer passivation layer 150A in the opening 120 and the RDL 130 above the bottom of the opening 120, and the interface between the hole 152 and the single-layer passivation layer 150A has an arcuate contour. The hole 152 can serves as a buffer between the single-layer passivation layer 150A and the RDL 130 to reduce undesired stress as a result of mismatch of thermal expansion coefficients between the single-layer passivation layer 150A and the RDL 130. Furthermore, when the external temperature or pressure changes drastically, the single-layer passivation layer 150A can also be prevented from excessively pulling the RDL 130, thereby preventing the RDL 130 close to the conductive pad 102B from peeling off or breaking.

Referring to FIG. 1I, in some embodiments, after forming the passivation layer structure (i.e., the single-layer passivation layer 150A), a metal layer 160 is formed in each of the openings that are formed in the ingle-layer passivation layer 150A and extends on the single-layer passivation layer 150A. For example, each metal layer 160 extends through the single-layer passivation layer 150A via the opening, and is electrically connected to the RDL 130 on the backside surface 100B of the substrate 100W. The metal layer 160 serves as a conductive connector that electrically connects to external circuits. The metal layer 160 may have a multi-layer structure. In order to simplify the diagram, only a single layer is depicted herein. In some embodiments, the metal layer 160 is a metal stack composed of a copper layer, a nickel layer, and a gold layer.

Referring to FIG. 1J, in some embodiments, after the metal layer 160 is formed, the carrier substrate 116 is de-bonded and the stop layer 108 and the passivation layer structure (i.e., the single-layer passivation layer 150A) are diced along the scribe line SL to form a singulated chip package 10A, as shown in FIG. 2. In some embodiments, when the adhesive layer 112 and/or the tape layer 114 is made of a light-to-heat conversion (LTHC) material, a de-bonding process is performed by irradiating the adhesive layer 112 with laser light or ultraviolet light. Due to the heat generated by laser light or ultraviolet light, the light-to-heat conversion (LTHC) material will decompose, so the carrier substrate 116 is removed from the structure including the substrate 100W.

Referring to FIG. 2 again, in some embodiments, the singulated chip package 10A includes a device substrate 100 diced from the substrate 100W and corresponding to the chip region C, a metallization layer 102, RDLs 130, a single-layer passivation layer 150A (passivation layer structure) and a stop layer 108. The metallization layer 102 and the RDLs 130 are disposed on the front side surface 100A and the backside surface 100B of the device substrate 100, respectively. The single-layer passivation layer 150A covers the edge surface 100E surrounding the device substrate 100, extends onto the backside surface 100B, and covers the RDLs 130. The remaining stop layer 108 in the metallization layer 102 is aligned with the single-layer passivation layer 150A covering the edge surface 100E to surround the device substrate 100 and to be in direct contact with the single-layer passivation layer 150A.

In some embodiments, the opening 120 in the device substrate 100 extends from the backside surface 100B to the front side surface 100A, and the RDL 130 extends into the corresponding opening 120 and is electrically connected to the corresponding conductive pad 102B in the metallization layer 102. Furthermore, the single-layer passivation layer 150A also extends into the opening 120 to block the opening 120, and a hole 152 is formed between the single-layer passivation layer 150A in the opening 120 and the RDL 130 in the opening 120.

In some embodiments, in the singulated chip package 10A, the insulating liner 122 is disposed between the device substrate 100 and the RDLs 130, and the metal layer 160 passes through the single-layer passivation layer 150A to be electrically connected to the RDL 130.

In some embodiments, the single chip package 10A also includes an optical component 104 disposed outside the chip package 10C, which is disposed on the metallization layer 102 and corresponds to the sensing device 100S in the device substrate 100.

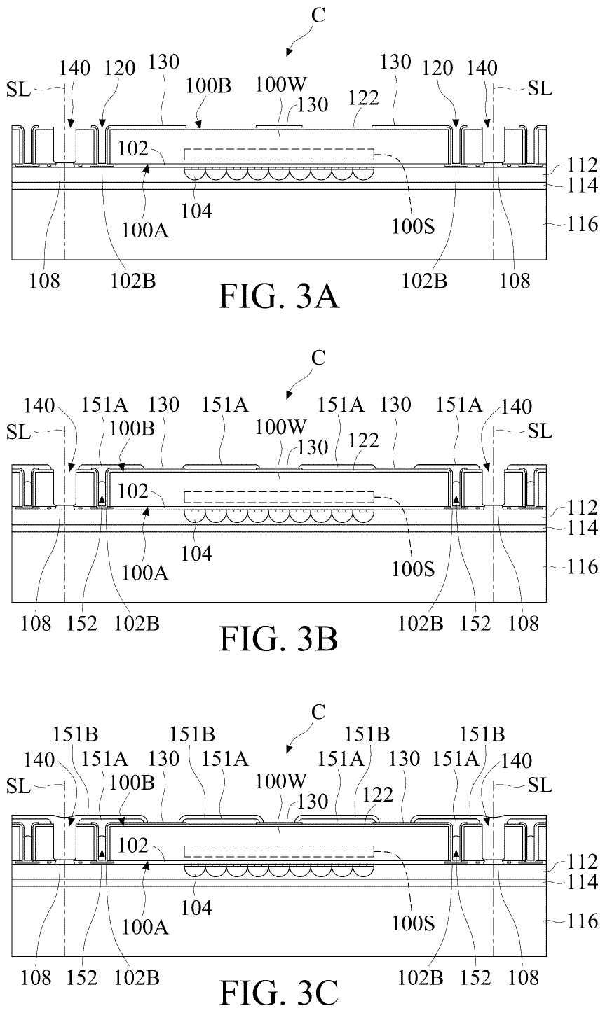

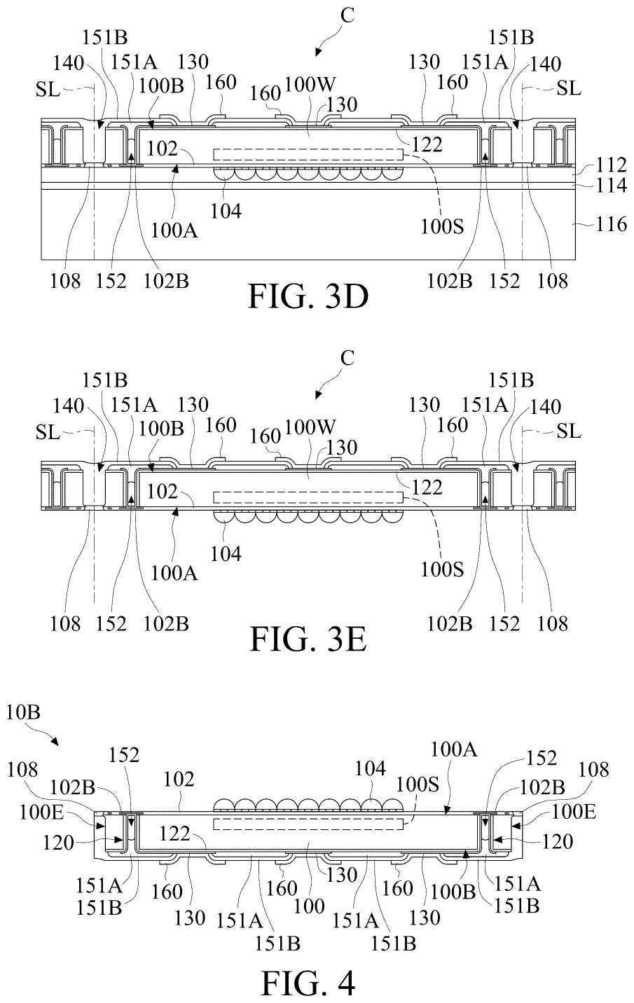

FIGS. 3A to 3E are cross-sectional views of a method for forming a chip package according to some embodiments. Elements in FIGS. 3A to 3E that are the same as those in FIGS. 1A to 1J are labeled with the same reference numbers as in FIGS. 1A to 1J and are not described again for brevity. Refer to FIG. 3A. In some embodiments, a structure as shown in FIG. 1G is provided.

Afterwards, referring to FIGS. 3B and 3C, in some embodiments, a passivation layer structure is formed on the backside surface 100B of the substrate 100W. The passivation layer structure covers the RDLs 130 and extends into the openings 120 and 140. In some embodiments, the passivation layer structure has a multi-layer structure. For example, the passivation layer structure is formed of a first passivation layer 151A and a second passivation layer 151B. As shown in FIG. 3B, in some embodiments, the first passivation layer 151A is formed to cover the RDLs 130 over the backside surface 100B of the substrate 100W. Similar to the single-layer passivation layer 150A shown in FIG. 1H, the first passivation layer 151A blocks but does not fully fill the opening 120. For example, a hole 152 is formed between the first passivation layer 151A in the opening 120 and the RDL 130 on the bottom of the opening 120, and the interface between the hole 152 and the first passivation layer 151A has an arcuate contour. In addition, unlike the single-layer passivation layer 150A shown in FIG. 1H, the first passivation layer 151A does not fill the opening 140, so that the first passivation layer 151A is exposed from the opening 140.

Afterwards, the first passivation layer 151A is patterned to form openings in the patterned first passivation layer 151A to expose the RDLs 130 below. The portions of the RDLs 130 exposed from the openings serve as pad regions for electrically connecting to external circuits (not shown). The material and formation method of the first passivation layer 151A may be similar to or the same as the material and formation method of the single-layer passivation layer 150A.

As shown in FIG. 3C, in some embodiments, a second passivation layer 151B is formed to cover the first passivation layer 151A and fully fill the exposed opening 140. Next, similar to patterning the first passivation layer 151A, The second passivation layer 151B is also patterned, so that openings are formed in the patterned second passivation layer 151B and aligned with the openings formed in the first passivation layer 151A, so as to expose the RDLs 130. The second passivation layer 151B may be made of an organic polymer material (such as solder mask or the like) that is different than that of the first passivation layer 151A. Since the solder mask has better light shielding properties than that of the organic polymer material that is utilized to form the first passivation layer 151A, it can be used as a light shielding layer to cover the edge surface of the substrate, thereby shielding or absorbing the light passing through the substrate of the sensing chip. Therefore, the problem of optical crosstalk effect can be eliminated or mitigated.

Referring to the FIG. 3D, in some embodiments, after forming the passivation layer structure (including the first passivation layer 151A and the second passivation layer 151B), the metal layer 160 is formed in each opening in the passivation layer 151A and the second passivation layer 151B and extends over the second passivation layer 151B. The metal layer 160 is electrically connected to the RDL 130 on the backside surface 100B of the substrate 100W via these openings.

Referring to FIG. 3E, in some embodiments, after forming the metal layer 160, the carrier substrate 116 is removed and the stop layer 108 and the second passivation layer 151B are diced along the scribe line SL to form a singulated chip package 10B, as shown in FIG. 4.

Referring to FIG. 4 again, in some embodiments, the singulated chip package 10B includes the device substrate 100 diced from the substrate 100W and corresponding to the chip region C, the metallization layer 102, and the RDLs 130, the passivation layer structure (including the first passivation layer 151A and the second passivation layer 151B) and the stop layer 108. The metallization layer 102 and the RDLs 130 are disposed on the front side surface 100A and the backside surface 100B of the device substrate 100, respectively. The second passivation layer 151B covers the edge surface 100E surrounding the device substrate 100, extends to the backside surface 100B, and covers the first passivation layer 151A and the RDLs 130. The remaining stop layer 108 in the metallization layer 102 is aligned with the second passivation layer 151B covering the edge surface 100E to surround the device substrate 100 and be in direct contact with the second passivation layer 151B.

In some embodiments, the first passivation layer 151A extends into the opening 120 to block the opening 120, and a hole 152 is formed between the first passivation layer 151A in the opening 120 and the RDL 130 in the opening 120.

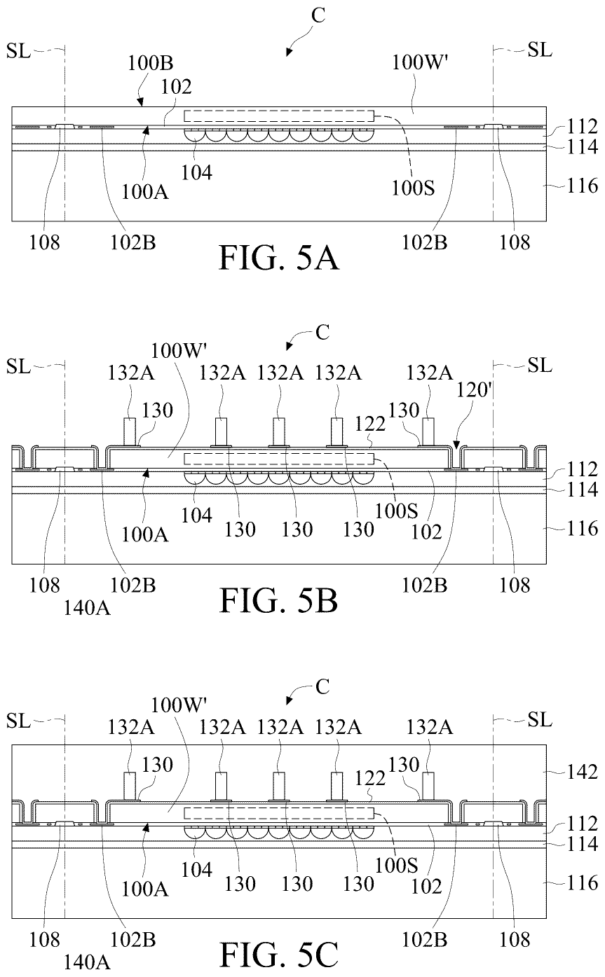

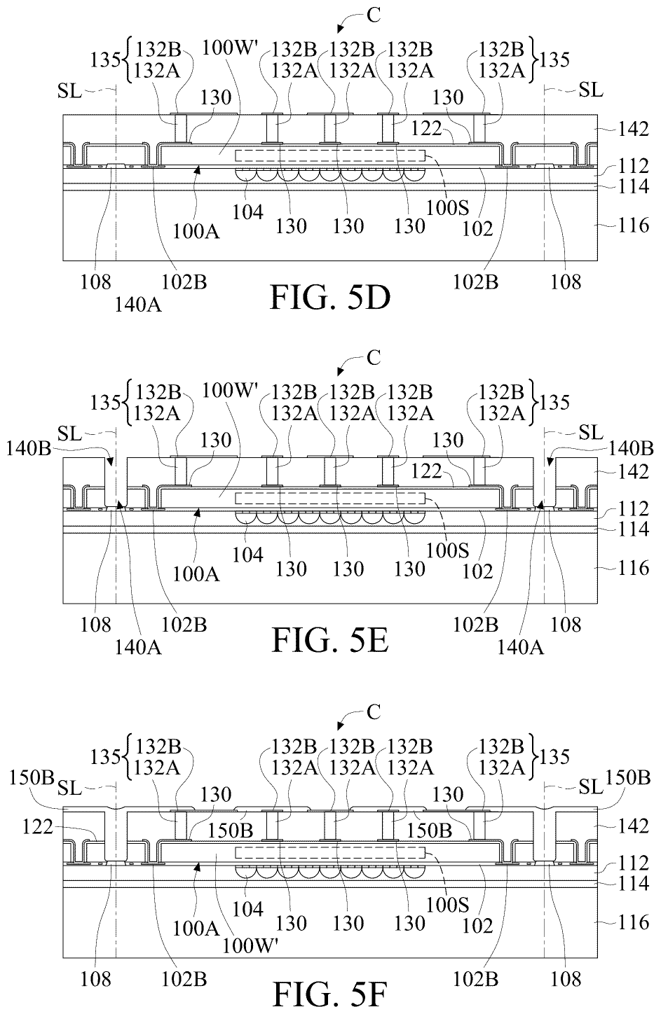

FIGS. 5A to 5H are cross-sectional views of a method for forming a chip package according to some embodiments. Elements in FIGS. 5A to 5H that are the same as those in FIGS. 1A to 1J are labeled with the same reference numbers as in FIGS. 1A to 1J and are not described again for brevity. Referring to FIG. 5A, in some embodiments, a structure as shown in FIG. 1D is provided. Afterwards, a thinning process (e.g., etching process, milling process, grinding process or polishing process) is performed on the backside surface 100B of the substrate 100W′ to reduce the thickness of the substrate 100W′. After the thinning process, the thickness of the substrate 100W′ is thinner than the thickness of the substrate 100W shown in FIG. 1D.

Referring to FIG. 5B, in some embodiments, after performing the thinning process, one or more openings are formed in the substrate 100W′ and extend from the backside surface 100B to the front side surface 100A of the substrate. For example, one or more openings 120′ are formed in the substrate 100W′ of each chip region C. The openings 120′ penetrate the substrate 100W′ and extend into the metallization layer 102 to expose the conductive pads 102B. Next, an insulating liner 122 (also referred to as an electrical isolation layer) is conformally formed on the backside surface 100B of the substrate 100W′. The insulating liner 122 is also conformally deposited on the sidewall surface of opening 120′. Afterwards, patterned redistribution layers (RDLs) 130 are formed on the insulating liner 122 over the backside surface 100B of the substrate 100W′. The RDL 130 also conformally extends to the sidewall surface and the bottom surface of the opening 120′, and is directly or indirectly electrically connected to the exposed conductive pad 102B through the opening 120′.

In some embodiments, after forming the RDLs 130, one or more conductive pillars 132A are formed on the corresponding RDLs 130. The conductive pillars 132A can be made of metal, such as copper or a similar metal, and can be formed using an electroplating process.

Referring to FIG. 5C, in some embodiments, a molding compound material layer 142 is formed to cover the backside surface 100B of the substrate 100W′ and the RDLs 130, and surround each conductive pillar 132A. Furthermore, the molding compound material layer 142 also fills the openings 120′.

In some embodiments, the height of the molding compound material layer 142 is higher than the height of the conductive pillars 132A, so that the upper surfaces of the conductive pillars 132A are covered by the molding compound material layer 142. The molding compound material layer 142 can provide structural support for the thinner substrate 100W′, thereby compensating for the insufficient rigidity of the substrate 100W′.

Referring to FIG. 5D, in some embodiments, a thinning process (e.g., etching process, milling process, grinding process or grinding process) is performed on the upper surface of the molding compound material layer 142 until the conductive pillars 132A are exposed. Afterwards, in some embodiments, one or more conductive wire layers 132B are formed on the molding compound material layer 142 and connected to the corresponding conductive pillars 132A to form other RDLs 135 (also referred to as redistribution structures). The material and formation method of the conductive wire layers 132B may be similar to or the same as the material and formation method of the RDLs 130.

Referring to FIG. 5E, in some embodiments, an opening 140B in the molding compound material layer 142 and an opening 140A in the substrate 100W′ are successively formed. Openings 140A and 140B are aligned with the scribe line region SL to surround the chip region C and expose the stop layer 108 in the metallization layer. In some embodiments, a sawing process may be performed along the scribe line region SL to sequentially form the openings 140B and 140A. In some embodiments, opening 140A extends through substrate 100W′ and partially extends into stop layer 108. For example, the opening 140A extends to half the stop layer 108 thickness. In some other embodiments, the opening 140A extends through substrate 100W′, but does not extend into stop layer 108.

Referring to FIG. 5F, in some embodiments, a passivation layer structure is formed on the backside surface 100B of the substrate 100W′. The passivation layer structure covers the RDL 130 and extends into the openings 140B and 140A. In some embodiments, the passivation layer structure has a single-layer structure. For example, the passivation layer structure is formed of the single-layer passivation layer 150B. Afterwards, the single-layer passivation layer 150B is patterned, so that openings are formed in the patterned single-layer passivation layer 150B to expose the underlying RDL 130. Portions of the RDL 130 exposed through the openings serve as pad regions for electrically connecting to external circuits (not shown). As shown in FIG. 5F, the single-layer passivation layer 150B fully fills the openings 140B and 140A. The material and formation method of the single-layer passivation layer 150B may be similar to or the same as the material and formation method of the second passivation layer 151B shown in FIG. 3C.

Referring to FIG. 5G, in some embodiments, after forming the passivation layer structure (i.e., the single-layer passivation layer 150B), a metal layer 160 is formed in each opening in the single-layer passivation layer 150B and extends over the single-layer passivation layer 150B. For example, each metal layer 160 extends through the single-layer passivation layer 150B via the opening and is electrically connected to the conductive wire layer 132B of the RDL 135 over the molding compound material layer 142. The metal layer 160 serves as a conductive connector that is electrically connected to external circuits.

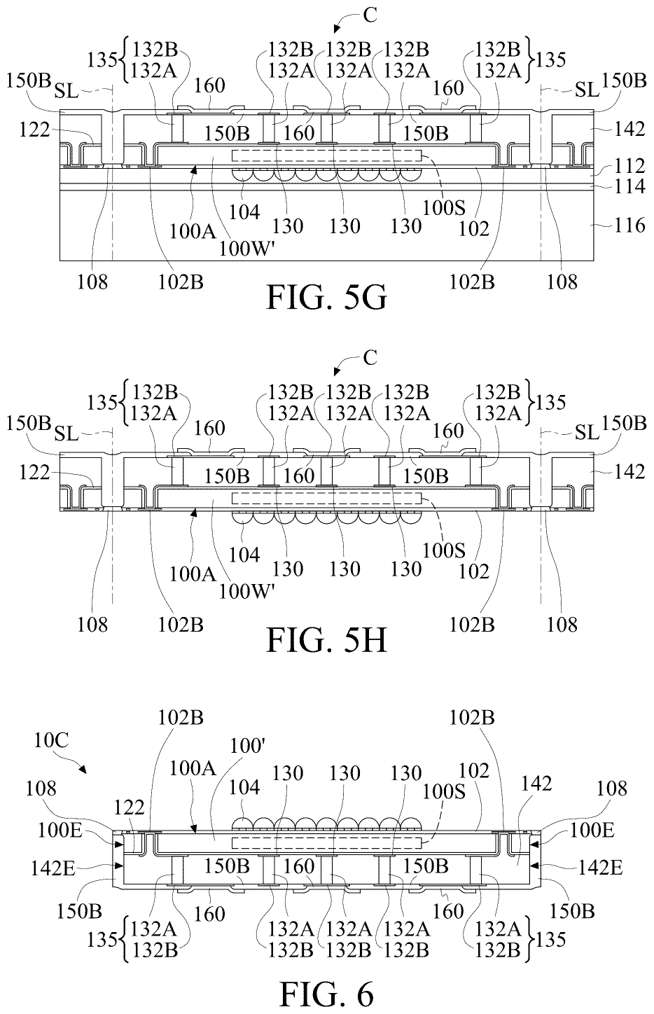

Referring to FIG. 5H, in some embodiments, after forming the metal layer 160, the carrier substrate 116 is removed and the stop layer 108 and the passivation layer structure (i.e., a single-layer passivation layer 150B) are diced along the scribe line region SL to form a singulated chip package 10C, as shown in FIG. 6.

Referring to FIG. 6 again, in some embodiments, the singulated chip package 10C includes a device substrate 100′ diced from the substrate 100W′ and corresponding to the chip region C, a metallization layer 102, RDLs 130 and 135, a molding compound material layer 142, a single-layer passivation layer 150B (passivation layer structure), and a stop layer 108. The metallization layer 102 and the RDL 130 are respectively disposed on the front side surface 100A and the backside surface 100B of the device substrate 100′. The single-layer passivation layer 150B covers the edge surface 100E surrounding the device substrate 100′ and the edge surface 142E of the molding compound material layer 142, and extends on the molding compound material layer 142 to cover the conductive wire layer 132B of the RDL 135. The remaining stop layer 108 in the metallization layer 102 is aligned with the single-layer passivation layer 150B that covers edge surfaces 100E and 142E to surround the device substrate 100′ and the molding compound material layer 142 and be in contact with the single-layer passivation layer 150B.

In some embodiments, the opening 120′ in the device substrate 100′ extends from the backside surface 100B to the front side surface 100A, and the RDL 130 extends into the corresponding opening 120′ and is electrically connected to the corresponding conductive pad 102B in the metallization layer 102. Furthermore, the conductive wire layer 132B on the molding compound material layer 142 is electrically connected to the corresponding RDL 130 via the corresponding conductive pillar 132A.

In some embodiments, in the singulated chip package 10C, the insulating liner 122 is disposed between the device substrate 100′ and the RDL 130, and the metal layer 160 passes through the single-layer passivation layer 150B to be electrically connected to the conductive wire layer 132B.

In some embodiments, the singulated chip package 10C also includes an optical component 104 disposed outside the chip package 10A. The optical component 104 is disposed on the metallization layer 102 and corresponds to the sensing device 100S in the device substrate 100′.

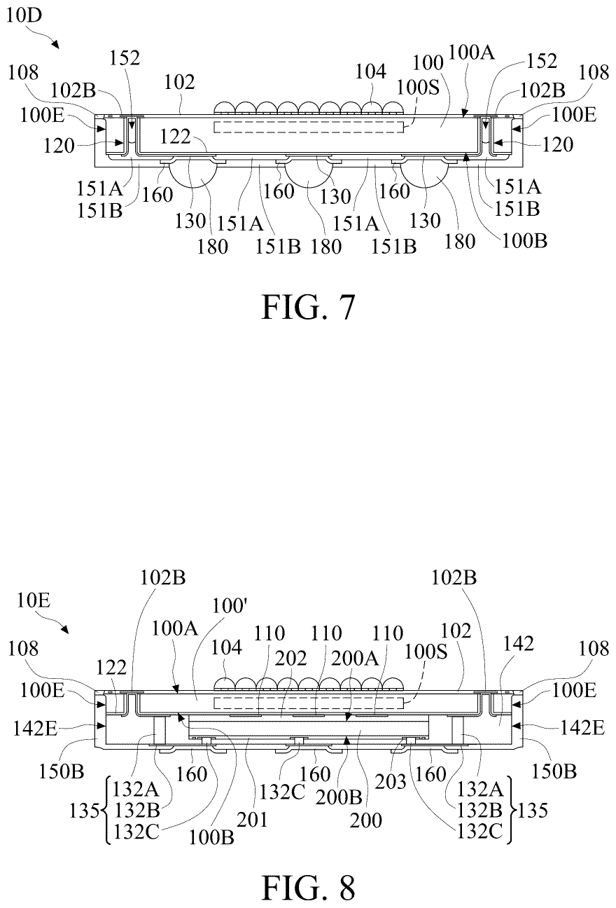

Refer to FIG. 7, which illustrates a cross-sectional view of a chip package 10D according to some embodiments. Elements in FIG. 7 that are the same as those in FIG. 4 are labeled with the same reference numbers as in FIG. 4 and are not described again for brevity. In some embodiments, the structure of the chip package 10D is similar to the chip package 10B of FIG. 4, and therefore the method for forming the chip package 10D is also similar to the method for forming the chip package 10B, as shown in FIGS. 3A to 3E.

The second passivation layer 151B in chip package 10B covers the first passivation layer 151A and the RDLs 130, and the metal layer 160 in chip package 10B is formed in each opening in the first passivation layer 151A and the second passivation layer 151B and extends over the second passivation layer 151B. Unlike the second passivation layer 151B and the metal layers 160 in the chip package 10B, the second passivation layer 151B in the chip package 10D is formed after forming the metal layers 160.

As shown in FIG. 7, in some embodiments, the metal layer 160 is formed in each opening in the passivation layer 151A and partially extends over the first passivation layer 151A. The second passivation layer 151B covers the edge surface 100E surrounding the device substrate 100, and extends to the backside surface 100B to cover the first passivation layer 151A and the edge portion of each metal layer 160 (i.e., the portion of the metal layer 160 that partially extends over the first passivation layer 151A). In other words, the metal layer 160 partially extends between the first passivation layer 151A and the second passivation layer 151B. Each metal layer 160 that is uncovered by or exposed from the second passivation layer 151B is connected to a conductive connection structure 180 (e.g., solder balls, bumps or conductive pillars), so as to be electrically connected to the corresponding RDL 130.

Refer to FIG. 8, which illustrates a cross-sectional view of a chip package 10E according to some embodiments. Elements in FIG. 8 that are the same as those in FIG. 6 are labeled with the same reference numbers as in FIG. 6 and are not described again for brevity. In some embodiments, the structure of the chip package 10E is similar to the chip package 10C of FIG. 6, and therefore the method for forming the chip package 10E is also similar to the method for forming the chip package 10C, as shown in FIGS. 5A to 5H.

Unlike the chip package 10C shown in FIG. 6, the chip package 10E includes a singulated device substrate 100′ stacked on the molding compound material layer 142. A device substrate 200 that is formed in the molding compound material layer 142 and has an active surface 200B and a backside surface 200A opposite the active surface 200B. The backside surface 200A of the device substrate 200 is bonded to the backside surface 100B of the device substrate 100′ via an adhesive layer 202, as shown in FIG. 8. For example, the adhesive layer 202 may be a die attach film. The device substrate 200 also includes an insulating layer 201 and one or more pads 203 disposed on the active surface 200B of the device substrate 200. In some embodiments, the insulating layer 201 includes an interlayer dielectric (ILD) layer, an inter-metal dielectric (IMD) layer, a passivation layer, or a combination thereof. Furthermore, the pads 203 are formed in the insulating layer 201 and have a top surface exposed from the insulating layer 201 to serve as an input/output (I/O) pad.

In some embodiments, the chip package 10E further includes conductive pillars 132A and conductive pillars 132C formed in the molding compound material layer 142. The conductive pillars 132A extend between the RDL 130 and the conductive wire layer 132B, and the conductive pillars 132C extend between the pads 203 of the device substrate 200 and the conductive wire layer 132B.

According to the foregoing embodiments, the edge surface of the device substrate in the chip package is covered by the passivation layer structure. Therefore, the chip itself can be prevented from warping or deforming due to insufficient rigidity, thereby reducing the difficulty of chip packaging. Furthermore, according to the foregoing embodiments, in a chip package having a thinner device substrate design, the structural strength of the chip can be enhanced via a molding compound material layer additionally disposed on the backside surface of the device substrate and via a passivation protective layer structure covering the edge surface of the device substrate. In addition, the passivation layer structure can include an organic polymer material with better light-shielding properties, and therefore can be used as a light-shielding layer covering the edge surface of the substrate, thereby eliminating or mitigating the problem of optical crosstalk effect.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A chip package, comprising:
a device substrate having an edge surface surrounding the device substrate;
a metallization layer disposed on a front side surface the device substrate;
a first redistribution layer disposed on a backside surface of the device substrate and extending into the device substrate;
a passivation layer structure surrounding and covering the edge surface of the device substrate, and extending to the backside surface and covering the first redistribution layer; and
a stop layer disposed in the metallization layer and aligned with the passivation layer structure covering the edge surface to surround the device substrate.

2. The chip package as claimed in claim 1, further comprising:
an electrical isolation layer disposed between the device substrate and the first redistribution layer.

3. The chip package as claimed in claim 1, further comprising:
a metal layer passing through the passivation layer structure to be electrically connected to the first redistribution layer.

4. The chip package as claimed in claim 1, wherein the device substrate has an opening extending from the backside surface to the front side surface of the device substrate, and the first redistribution layer extends into the opening and is electrically connected to a conductive pad in the metallization layer.

5. The chip package as claimed in claim 4, wherein the passivation layer structure extends into the opening to block the opening, and wherein the passivation layer structure is made of a single-layer of organic polymer material.

6. The chip package as claimed in claim 4, wherein the passivation layer structure comprises:
a first passivation layer covering the first redistribution layer on the backside surface of the device substrate and extending into the opening to block the opening; and
a second passivation layer covering the first passivation layer and in direct contact with the edge surface of the device substrate.

7. The chip package as claimed in claim 6, further comprising:
a metal layer passing through the first passivation layer and partially extending between the first passivation layer and the second passivation layer, wherein the metal layer is electrically connected to the first redistribution layer.

8. The chip package as claimed in claim 1, further comprising:
a molding compound material layer having a first surface covering the first redistribution layer on the backside surface of the device substrate; and
a second redistribution layer disposed on a second surface of the molding compound material layer opposite to the first surface, and extending into the molding compound material layer to be electrically connected to the first redistribution layer.

9. The chip package as claimed in claim 8, further comprising:
a second device substrate disposed in the molding compound material layer, wherein the second device substrate has a backside surface covering the first redistribution layer and bonded to the backside surface of the device substrate and an active side surface electrically connected to the second redistribution layer.

10. The chip package as claimed in claim 8, wherein the second redistribution layer comprises:
a conductive wire portion on the second surface of the molding compound material layer;
a first conductive pillar portion in the molding compound material layer and connected to the conductive wire portion and the first redistribution layer; and
a second conductive pillar portion in the molding compound material layer and connected to the conductive wire portion and the active side surface of the second device substrate.

11. The chip package as claimed in claim 8, wherein the passivation layer structure surrounds and covers an edge surface of the molding compound material layer, and extends to the second surface and covers the second redistribution layer, and wherein the passivation layer structure is made of a single-layer of organic polymer material.

12. The chip package as claimed in claim 8, further comprising:
a metal layer passing through the passivation layer structure to be electrically connected to the second redistribution layer.

13. The chip package as claimed in claim 8, wherein the second redistribution layer comprises:
a conductive wire portion on the second surface of the molding compound material layer; and
a conductive pillar portion in the molding compound material layer and connected to the conductive wire portion and the first redistribution layer.

14. The chip package as claimed in claim 8,
wherein the device substrate has an opening therein and extending from the backside surface to the front side surface of the device base;
wherein the first redistribution layer extends into the opening and is electrically connected to a conductive pad located in the metallization layer; and
wherein the molding compound material layer covers the first redistribution layer on the backside surface of the device substrate and extends into the opening to block the opening.

15. The chip package as claimed in claim 1, further comprising:
an optical component disposed on the metallization layer and corresponding to a sensing device in the device substrate, wherein the optical component is disposed outside the chip package.

16. The chip package as claimed in claim 1, wherein the stop layer is in direct contact with the passivation layer structure covering the edge surface.

17. A method for forming a chip package, comprising:
provide a substrate having a chip region and a scribe line region surrounding the chip region;
forming a metallization layer on a front side surface of the substrate, wherein the metallization layer has a first opening aligned with the scribe line region to surround the chip region;
forming a stop layer in the first opening;
forming a first redistribution layer on a backside surface of the substrate and extending into the substrate;
forming a second opening in the substrate and aligned with the scribe line region to surround the chip region and expose the stop layer; and
forming a passivation layer structure on the backside surface and filling the second opening, wherein the passivation layer structure covers the first redistribution layer.

18. The method as claimed in claim 17, further comprising:
before forming the first redistribution layer, forming an electrical isolation layer on the backside surface of the substrate and extending into the substrate, so that the electrical isolation layer separates the substrate from the first redistribution layer.

19. The method as claimed in claim 17, further comprising:
forming a metal layer on the passivation layer structure and extending through the passivation layer structure to be electrically connected to the first redistribution layer; and
dicing the stop layer and the passivation layer structure along the scribe line region.

20. The method as claimed in claim 17, further comprising:
before forming the first redistribution layer, forming a third opening in the substrate, so that the first redistribution layer extends into the substrate via the third opening.

21. The method as claimed in claim 20, wherein the passivation layer structure extends into the third opening to block the third opening, and wherein the passivation layer structure is made of a single-layer of organic polymer material.

22. The method as claimed in claim 20, wherein forming the passivation layer structure comprises:
forming a first passivation layer to cover the first redistribution layer on the backside surface of the substrate and block the third opening, wherein the first passivation layer exposes the second opening; and
forming a second passivation layer to cover the first passivation layer and fully fill the exposed second opening.

23. The method as claimed in claim 17, further comprising:
before forming the second opening, forming a conductive pillar on the first redistribution layer;
forming a molding compound material layer to cover the backside surface of the substrate and the first redistribution layer and surround the conductive pillar; and
forming a conductive wire layer on the molding compound material layer and connected to the conductive pillar to form a second redistribution layer with the conductive pillar.

24. The method as claimed in claim 23, further comprising:
before forming the second opening, a third opening is formed in the molding compound material layer and aligned with the scribe line region to surround the chip region, wherein the formed passivation layer structure covers the second redistribution layer and fully fills the third opening.

25. The method as claimed in claim 24, wherein the passivation layer structure is made of a single-layer of organic polymer material.

26. The method as claimed in claim 24, further comprising:
forming a metal layer through the passivation layer structure to be electrically connected to the second redistribution layer.

27. The method as claimed in claim 23, further comprising:
before forming the first redistribution layer, forming a third opening in the substrate, so that the first redistribution layer extends into the substrate via the third opening, wherein the molding compound material layer covers the first redistribution layer on the backside surface of the device substrate and blocks the third opening.

28. The method as claimed in claim 17, wherein the stop layer is in direct contact with the passivation layer structure in the second opening.
